(19) United States
(12) Patent Application Publication
(10) Pub. No.: US 2019/0377025 A1
(43) Pub. Date: Dec. 12, 2019

(54) MULTIPLEXED DLTS AND HSCV MEASUREMENT SYSTEM

(71) Applicant: Miasole Hi-Tech Corp., Santa Clara, CA (US)

(72) Inventor: Robert Jeffrey Bailey, Scotts Valley, CA (US)

(21) Appl. No.: 16/003,534

(22) Filed: Jun. 8, 2018

(51) Int. Cl. G01R 31/312; H02S 50/10; G01R 31/265; G01R 31/26

(52) U.S. Cl. CPC G01R 31/312; G01R 31/2621; G01R 31/265; H02S 50/10

(57) ABSTRACT

Techniques and systems are described that enable multiplexed DLTS and HSCV measurements.

### BACKGROUND

In a semiconductor material, deviations from the crystalline lattice structure may correspond to physical defects. Certain types of these physical defects have an impact on the electrical characteristics of the semiconductor material, such as in the form of a charge carrier trap that affects the mobility of charge carriers such as free electrons or electron holes. Some traps are referred to as deep traps because the energy to free a charge carrier from the deep trap exceeds the characteristic thermal energy. The impeded mobility of charge carriers impacts the operation of transistors, light emitting diodes, photovoltaic cells, and so forth. As one example, a failure mode of metal oxide semiconductor field effect transistors (MOSFETs) relates to Bias Temperature Instability (BTI), which occurs when traps cause the operating threshold voltage of the transistor to shift when traps are filled with charge carriers. As another example, Copper-Indium-Gallium-Selenide (CIGS) solar cells can have a class of defects with metastable behavior, such as in response to light or hysteresis effects, thereby complicating CIGS device characterization.

Deep-level transient spectroscopy (DLTS) is a capacitance-based device characterization method used widely in semiconductor and photovoltaic (PV) applications to determine the number and type of charge-trapping defects in the active area of a solar or semiconductor device. High-speed CV (HSCV) is another method for profiling charge distributions in semiconductor devices, sometimes with greater precision than a DLTS system. In HSCV, a voltage sweep occurs in a short time interval such that charge-trapping defects can neither trap free carriers nor release their trapped carriers, thereby avoiding associated capacitance transients.

DLTS and HSCV are versatile semiconductor device characterization methods. Conventionally, however, they have been performed sequentially, requiring separate analyses that potentially represent different device states. For instance, in CIGS solar cells, due to their particular set of defect characteristics, it is common that a DLTS measurement changes the state of the device such that a HSCV measurement yields different results before and after the DLTS measurement. How the CIGS device changes during DLTS is not directly measurable because the HSCV and DLTS methods are conventionally performed sequentially.

### SUMMARY

One aspect of the subject matter described herein relates to an apparatus including: a first input configured to interface to a semiconductor device; a first output configured to interface to the semiconductor device; first circuitry configured to generate a set of waveform cycles at the first output, each cycle having: a first temporal portion having a first signal configured to fill a set of charge-trapping defects in the semiconductor device with free carriers; a second temporal portion having a second signal configured to cause a subset of the free carriers to retract from the set of charge-trapping defects based on a time constant; a first subset of cycles corresponding to less than the entire set of waveform cycles further having: a third signal and a fourth signal during the second temporal portion, the third signal and the fourth signal being configured to cause a corresponding number of free carriers filled and/or retracted from the set of charge-trapping defects to be within a constraint, the third signal occurring earlier than the second signal, the fourth signal occurring later than the second signal. The apparatus also includes second circuitry configured to measure a first set of capacitance characteristics at the first input based in part on the third signal and a second set of capacitance characteristics at the first input based in part on the fourth signal for determining a change in charge depth profiles in the semiconductor device at different times during the second temporal portion.

In some implementations, the semiconductor device is a photovoltaic cell. In some implementations, the photovoltaic cell is a copper-indium-gallium-selenide (cigs) photovoltaic cell. In some implementations, a time duration for the third signal is selected such that a difference between a first sample value from a capacitance transient during the third signal and a second sample value from a second capacitance transient during the second temporal portion of a cycle not included in the first subset of cycles is below a threshold value. In some implementations, the threshold value is about 3 pf. In some implementations, the third signal has: a time duration of about 1 ms; about 25 voltage steps; and a voltage range of about −1 v to about −0.2 v. In some implementations, the third signal and the fourth signal have the same time duration, number of voltage steps, and voltage range. In some implementations, a single cycle in the first subset of cycles follows a single cycle not in the first subset of cycles. In some implementations, each cycle in the first subset of cycles includes three voltage ramps for measuring capacitance characteristics at the first input for determining changes in charge depth profiles in the semiconductor device during the second temporal portion, the three voltage ramps including the third signal and the fourth signal. In some implementations, a first subset of the set of charge-trapping defects corresponds to metastable defects that are responsive to at least one of light or hysteresis effects. Implementations of the described techniques may include hardware, a method or process, or computer software on a computer-accessible medium.

Another aspect of the subject matter described herein relates to a method including: generating a set of waveform cycles at a first output configured to interface to a semiconductor device, each cycle having: a first temporal portion having a first signal configured to fill a set of charge-trapping defects in the semiconductor device with free carriers; a second temporal portion having a second signal configured to cause a subset of the free carriers to retract from the set of charge-trapping defects based on a time constant; a first subset of cycles corresponding to less than the entire set of waveform cycles further having: a third signal and a fourth signal during the second temporal portion, the third signal and the fourth signal being configured to cause a corresponding number of free carriers filled and/or retracted from the set of charge-trapping defects to be within a constraint, the third signal occurring earlier than the second signal, the fourth signal occurring later than the second signal. The method also includes measuring at a first input configured to interface to the semiconductor device a first set of capacitance characteristics based in part on the third signal and a second set of capacitance characteristics at the first input based in part on the fourth signal for determining a change in charge depth profiles in the semiconductor device at different times during the second temporal portion.

In certain implementations, the semiconductor device is a photovoltaic cell. In certain implementations, the photovoltaic cell is a copper-indium-gallium-selenide (cigs) photovoltaic cell. In certain implementations, a time duration for the third signal is selected such that a difference between a first sample value from a capacitance transient during the third signal and a second sample value from a second capacitance transient during the second temporal portion of a cycle not included in the first subset of cycles is below a threshold value. In certain implementations, the threshold value is about 3 pf. In certain implementations, the third signal has: a time duration of about 1 ms; about 25 voltage steps; and a voltage range of about −1 v to about −0.2 v. In certain implementations, the third signal and the fourth signal have the same time duration, number of voltage steps, and voltage range. In certain implementations, a single cycle in the first subset of cycles follows a single cycle not in the first subset of cycles. In certain implementations, each cycle in the first subset of cycles includes three voltage ramps for measuring capacitance characteristics at the first input for determining changes in charge depth profiles in the semiconductor device during the second temporal portion, the three voltage ramps including the third signal and the fourth signal. In certain implementations, a first subset of the set of charge-trapping defects corresponds to metastable defects that are responsive to at least one of light or hysteresis effects.

Another aspect of the subject matter described herein relates to a computer program product comprising computer-readable program code to be executed by one or more processors when retrieved from a non-transitory computer-readable medium, the program code including instructions configured to cause: generating a set of waveform cycles at a first output configured to interface to a semiconductor device, each cycle having: a first temporal portion having a first signal configured to fill a set of charge-trapping defects in the semiconductor device with free carriers; a second temporal portion having a second signal configured to cause a subset of the free carriers to retract from the set of charge-trapping defects based on a time constant; a first subset of cycles corresponding to less than the entire set of waveform cycles further having: a third signal and a fourth signal during the second temporal portion, the third signal and the fourth signal being configured to cause a corresponding number of free carriers filled and/or retracted from the set of charge-trapping defects to be within a constraint, the third signal occurring earlier than the second signal, the fourth signal occurring later than the second signal. The method also includes measuring at a first input configured to interface to the semiconductor device a first set of capacitance characteristics based in part on the third signal and a second set of capacitance characteristics at the first input based in part on the fourth signal for determining a change in charge depth profiles in the semiconductor device at different times during the second temporal portion.

These and other aspects are described further below with reference to the drawings.

### BRIEF DESCRIPTION OF THE DRAWINGS

FIG. 1A depicts an example implementation of a multiplexed DLTS and HSCV measurement system.

FIG. 1B depicts an example flow diagram of a multiplexed DLTS and HSCV measurement system.

FIG. 1C depicts examples of voltages applied to a DUT in a DLTS measurement system.

FIG. 2 depicts examples of voltages applied to a DUT in a HSCV measurement system.

FIG. 3 depicts examples of voltages applied to a DUT in a multiplexed DLTS and HSCV measurement system.

FIG. 4 depicts further examples of variations in a DUT in response to HSCV measurements.

FIG. 5 depicts examples of variations in a DUT in response to HSCV measurements.

FIG. 6 depicts examples of variations in a DUT in response to different configurations of HSCV measurements.

### DETAILED DESCRIPTION

This disclosure describes systems and techniques for a multiplexed DLTS and HSCV measurement system. For example, when a CIGS solar cell is being characterized using the DLTS method, how the CIGS device changes during DLTS is measured using the HSCV method.

Deep-level transient spectroscopy (DLTS) is a capacitance-based device characterization method that can be used in semiconductor and PV applications to determine the number and type of charge-trapping defects in the active area of a solar or semiconductor device. Methods exist for the interpretation of DLTS spectra to obtain the activation energy of recombination-active defects, their capture cross-section, and their concentration. DLTS can be operated in digital mode, whereby the output of a fast capacitance meter is sampled digitally at a high rate during a capacitance transient that is induced by changing applied voltage to the device under test (DUT), such as a CIGS solar cell. The capacitance transients result from the evolving trapped charge profile in the device.

In DLTS, the temperature of the DUT can be varied, causing a change in the capacitance transient time constant. The relationship between the temperature and the time constant can be analyzed to determine the kinetics of emission of trapped charge in the device. By varying the voltage applied to the DUT, it is possible to control the depth of the injected carriers into the active area of the device. By repeating DLTS measurements at different voltage settings, it is possible to infer the location of the charge-trapping defects by comparing the magnitude of the DLTS response among different discrete voltage values. In this way, a concentration (e.g., charge depth) profile can be produced. In some scenarios, the DLTS method involves repeating measurements to perform a temperature sweep.

The capacitance-voltage (CV) technique is an example of another method for profiling charge distributions in semiconductor devices. In the CV technique, capacitance for a DUT is recorded over a range of applied voltage in a static device in times ranging from several seconds to a few minutes. From this capacitance-voltage relationship, it is possible to calculate the shallow dopant profile in the DUT. In some scenarios, the presence of charge-trapping defects that can induce capacitance transients and accumulate trapped charge in the active region complicates the interpretation of CV results.

The method of high-speed CV (HSCV) eliminates some of the problems with conventional CV in some devices. In HSCV, a voltage sweep occurs in as little as, for example, one millisecond. In some scenarios, for such a time interval, the charge-trapping defects do not trap free carriers nor release their trapped carriers, thereby there is no corresponding capacitance transient (e.g., the charge distribution is essentially frozen in place). The measured HSCV profile represents the total charge density (e.g., dopants plus ionized defects) based on a straightforward interpretation, and is useful to diagnose changing charge profiles in a device, and in certain scenarios, can help reveal the origin of the changes.

This disclosure describes systems and techniques for a multiplexed DLTS and HSCV measurement system. In certain implementations, because HSCV can diagnose changing charge profiles in a device, HSCV measurements performed during a DLTS measurement can reveal with precision the changing charge profile that yields the capacitance transient that DLTS processes and analyzes. The disclosed techniques integrate both DLTS and HSCV measurements simultaneously in a measurement on, for example, a digital data acquisition platform.

In a class of implementations, DLTS measurements are configured to employ a repeating pulse cycle, or waveform cycle, in which the capacitance transient can be continuously monitored and analyzed, each HSCV voltage sweep is configured to last, for example, about one millisecond, HSCV voltage sweeps are inserted periodically into the repeating DLTS pulse sequence, and the DLTS and HSCV signals can be processed independently.

It should be appreciated that the disclosed techniques can provide both a DLTS measurement as well as a simultaneous series of temperature-dependent charge profiles in approximately the same amount of time as the DLTS measurement itself. It should be noted that multiplexing DLTS and HSCV measurements can enable observation of the changing charge and/or effective doping profile that occurs during a DLTS measurement (e.g., use of HSCV to study charge evolution during capacitance transients in DLTS measurements). Examples of the voltage pulse sequence and the analysis of the recorded capacitance values are illustrated through the figures discussed below.

The particular signs (e.g., positive, negative) for voltage and capacitance values in the following figures are for example purposes, and the particular sign for a voltage or capacitance value may differ based on the configuration of the DUT and/or measurement set up. It should further be appreciated that the specific values and units for voltage and capacitance in the following figures are for example purposes, and values may be expressed as a relative change (e.g., ratios, percentages, delta values, and so forth), and/or the unit may differ based on the configuration of the DUT and/or measurement set up. It should also be appreciated that in some implementations, a current source can be used instead of a voltage source.

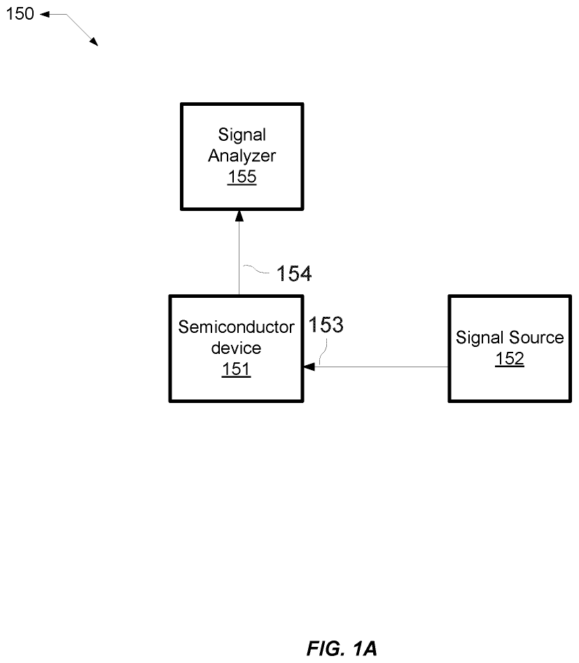

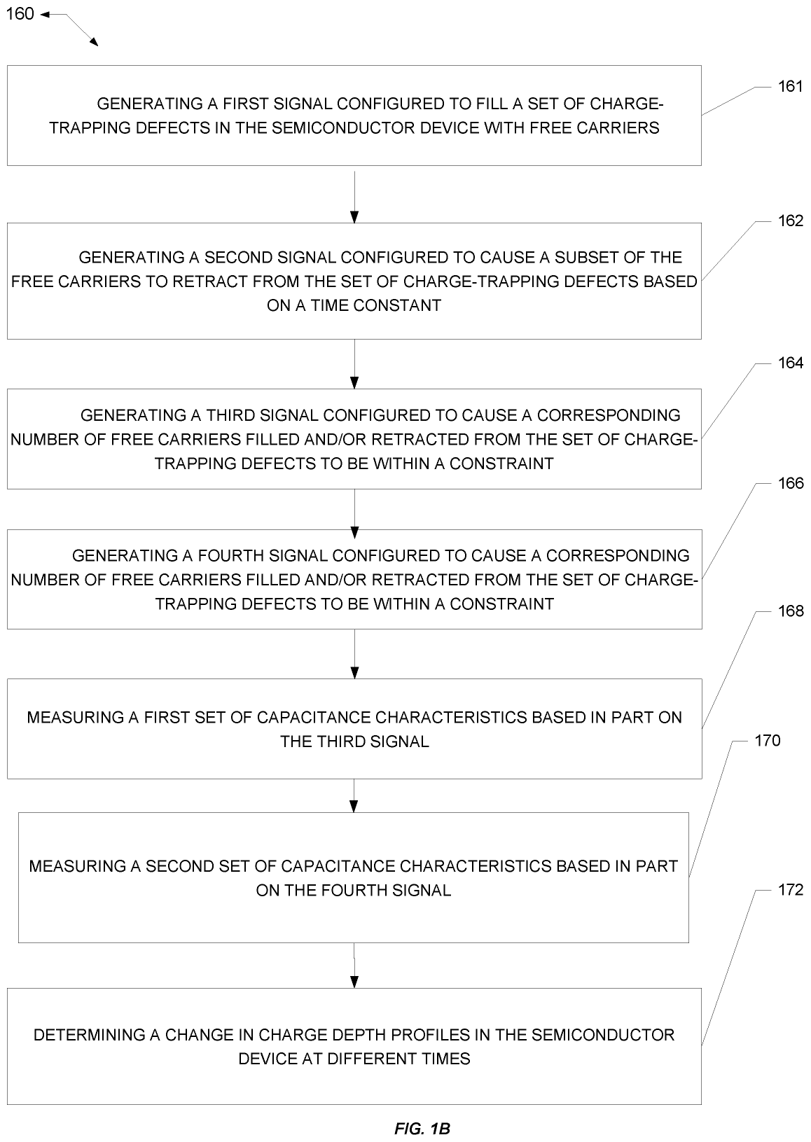

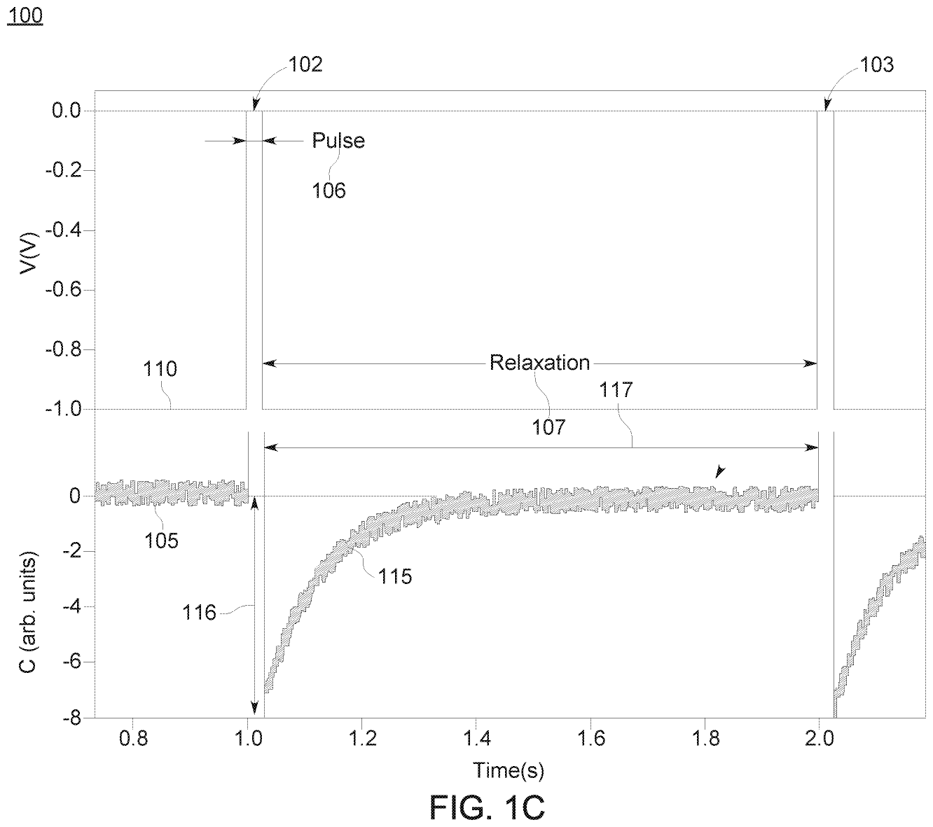

FIG. 1A depicts an example implementation of a multiplexed DLTS and HSCV measurement system 150. Circuitry in signal source 151 for generating the waveform cycles depicted in the following FIGS. 1C-6 may include one or more voltage and/or current sources for interfacing through output port 153 to one or more DUTs, such as semiconductor device 151, and can include but is not limited to function generators, arbitrary waveform generators, and so forth. Circuitry in signal analyzer 155 for measuring the waveforms and/or data points depicted in the following FIGS. 1C-6 may include one or more voltage, current, temperature, and/or capacitance sensors, meters, oscilloscopes, data acquisition (DAQ) devices, etc., for interfacing through input port 154 to one or more DUTs, such as semiconductor device 151. Configuration of components of multiplexed DLTS and HSCV measurement system 150, such as, for example, signal source 151 and signal analyzer 155, are described in further detail in relation to the discussions of FIGS. 1C-6 below.

FIG. 1B depicts an example flow 160 for a multiplexed DLTS and HSCV measurement system. In a class of implementations, the flow includes generating a set of waveform cycles at a first output of a signal source configured to interface to a semiconductor device (e.g., semiconductor device 151 in FIG. 1A). For example, at 161, the flow includes generating a first temporal portion having a first signal (e.g., a pulse phase) configured to fill a set of charge-trapping defects in the semiconductor device with free carriers. At 162, the flow includes generating a second temporal portion having a second signal (e.g., a relaxation phase) configured to cause a subset of the free carriers to retract from the set of charge-trapping defects based on a time constant.

In a subset of cycles, the flow also includes generating a third signal (164) and a fourth signal (166) during the second temporal portion (e.g., the relaxation phase), the third signal and the fourth signal (e.g., different HSCV voltage ramps) being configured to cause a corresponding number of free carriers filled and/or retracted from the set of charge-trapping defects to be within a constraint (e.g., the perturbation in a relaxation phase capacitance transient being constrained to, for example, less than 3 pF). As further described in detail in relation to the discussions of FIGS. 1C-6 below, the third signal occurs earlier than the second signal, and the fourth signal occurs later than the second signal, such that evolution of the charge depth profile during a capacitance transient can be observed.

The flow also includes measuring at a first input configured to interface to the semiconductor device a first set of capacitance characteristics based in part on the third signal (168) and a second set of capacitance characteristics at the first input based in part on the fourth signal (170). These different sets of capacitance characteristics, in relation to the respective third signal and fourth signal, are used at 172 for determining a change in charge depth profiles in the semiconductor device at different times during the second temporal portion. The examples discussed below in relation to FIG. 1C-6 will be instructive.

FIG. 1C illustrates a pair 100 of voltage versus time 110 and capacitance versus time 105 plots depicting examples of voltages applied to a DUT (e.g., a CIGS solar cell) in a DLTS measurement, and examples of capacitances in the DUT in response to the voltages applied. The repeating voltage profile applied to the device divides each period into two phases. During the “pulse” signal (e.g., phase 106) the DUT is biased at a voltage close to, for example, zero. During this time (depicted as approximately 10 milliseconds in FIG. 1C, as depicted by the pulse width 102, pulse width 103) the charge-trapping defects in the device active region become filled with free carriers. During the “relaxation” signal (e.g., phase 107) the voltage is held at, for example, a reverse bias voltage between about −0.5 to −2V to retract the free carriers from the device active region.

In FIG. 1C, the capacitance changes in two ways: during the pulse phase 106 the capacitance changes (e.g., capacitance change 116) due to the increased voltage on the DUT (reaching a value off-scale in FIG. 1C), and when the reverse bias is restored in the relaxation phase 107 the trapped carriers are emitted over time interval 117 with a characteristic time constant yielding a typically exponential change in capacitance (e.g., capacitance transient 115). A DLTS measurement system analyzes the capacitance transient during the relaxation phase using, for example, a high-speed acquisition of the capacitance transient from a fast capacitance meter.

In certain implementations, repeated pulsing and data acquisition are used to increase the signal-to-noise ratio as the temperature (and therefore, the capacitance transient time constant) continuously changes over time. For example, depicted in FIG. 1C is a DLTS measurement period of 1 second, and in various implementations, the temperature is slowly changing so that at least several (3-10) periods can be averaged at the same effective temperature. Background details of the DLTS method are described in LANG, D. V., “Deep-level transient spectroscopy: A new method to characterize traps in semiconductors” Journal of Applied Physics 45(7):3023-3032, 1974, the entire disclosure being incorporated herein by reference for all purposes.

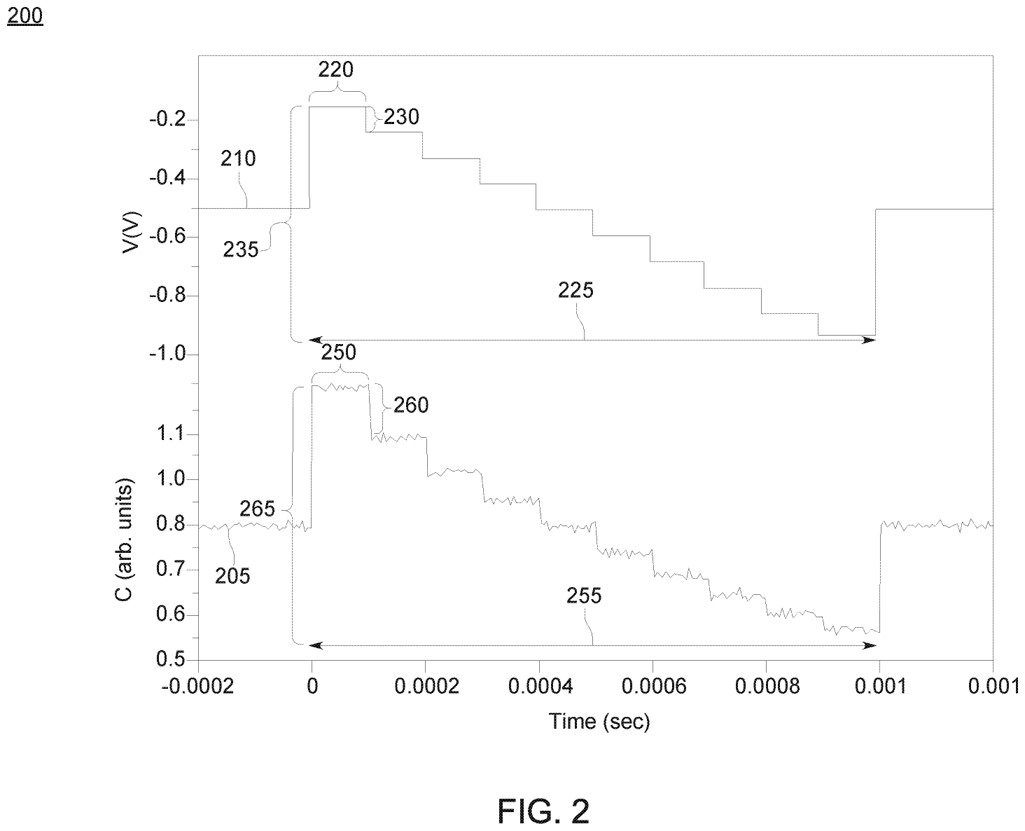

FIG. 2 illustrates a pair 200 of voltage versus time 210 and capacitance versus time 205 plots depicting examples of voltages applied to a DUT (e.g., a CIGS solar cell) in a HSCV measurement, and examples of capacitances in the DUT in response to the voltages applied. In FIG. 2, the voltage is ramped over 1 millisecond (depicted by time interval 225, time interval 255), beginning and ending at bounding voltages (depicted by voltage interval 235 beginning at approximately −0.1V and ending at approximately −1.0V, with corresponding overall capacitance change interval 265). At each voltage step (10 steps in the example depicted in FIG. 2) the capacitance can be averaged digitally, resulting in a series of C and V values (e.g., the voltage value 220 is associated with the capacitance value 250). It should be appreciated that the particular bounding voltages and the particular number of voltage steps during an HSCV voltage ramp is not limited to the examples as depicted in FIG. 2. For example, the particular number of voltage steps (or the voltage step size 230) is selected such that the dwell time at each voltage allows measuring a stable capacitance value after each capacitance step (e.g., capacitance change 260), together with restricting the total ramp time to no longer than about, for example, 1 millisecond. In a class of implementations, about 25 voltage steps are used. It should be appreciated that the voltage profile in FIG. 2 is a nonlimiting example, and that the dwell time at each voltage step may be non-uniform, the voltage step size may be non-uniform, a voltage step may be repeated, or voltage steps may not necessarily be sequentially decreasing or increasing, and so forth. Background details of the CV and HSCV methods are described in PAUL, et al., “Fast C-V method to mitigate effects of deep levels in CIGS doping profiles” arXiv:1706.09946 [physics.ins-det], 2017, and BOESCH, Jr., Edwin H., “Development of Apparatus for Performing Rapid Capacitance-Voltage Measurements on MIS Structures” Harry Diamond Laboratories, Report No. HDL-TM-76-33, 1976, the entire disclosures being incorporated herein by reference for all purposes.

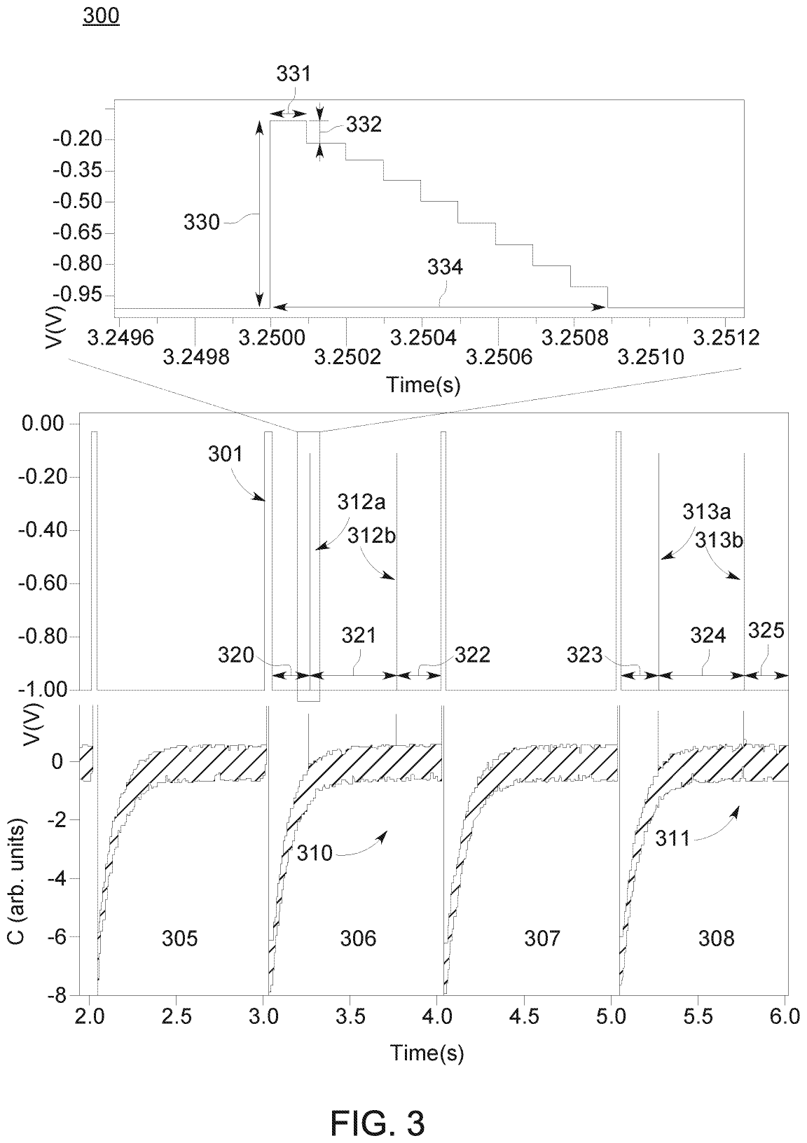

An example illustrating the method 300 to multiplex DLTS and HSCV measurements is depicted in FIG. 3. The voltage trace depicts several voltage pulse cycles (e.g., pulse cycle 305, pulse cycle 307) that represent the DLTS pulse cycle as discussed earlier for FIG. 1C. In the example of FIG. 3, based on a predefined ratio, DLTS pulse cycles are alternated with cycles containing one or more applied HSCV voltage ramps (e.g., pulse cycle 306 and pulse cycle 308). FIG. 3 illustrates a ratio of 1:1, corresponding to one DLTS pulse cycle followed by one HSCV pulse cycle. The ratio may vary, such as, for example, being a ratio of 1000:1, with 1000 DLTS pulse cycles for each HSCV pulse cycle. It should be appreciated that as referred to herein, one HSCV pulse cycle includes one or more HSCV measurements as previously discussed for FIG. 2.

For the DLTS pulse cycles, the capacitance transient is acquired and analyzed according to the DLTS method as discussed for FIG. 1C. In the HSCV pulse cycles, at predefined intervals, which can include an interval 320 between the beginning of the pulse cycle to a HSCV voltage ramp, interval 321 between HSCV voltage ramps, and/or interval 322 between a HSCV voltage ramp and the end of the pulse cycle, one or more HSCV voltage ramps are superimposed during the relaxation phase. Two are shown in FIG. 3 for HSCV pulse cycle 306 (e.g., voltage ramps 312a and 312b, with a zoomed up view of voltage ramp 312a in the top portion of FIG. 3), though it should be appreciated that the specific number of HSCV voltage ramps and the time duration of the intervals can vary from the examples shown in FIG. 3. In a class of implementations, voltage ramps within a HSCV pulse cycle, such as voltage ramp 312a and voltage ramp 312b, may be configured differently. Furthermore, in some implementations, the configuration of voltage ramps across different HSCV pulse cycles may differ (e.g., including but not limited to the voltage range 330, dwell time 331, voltage step size 332, timing interval 334, and so forth). For instance, in FIG. 3, the number of HSCV pulse cycles in pulse cycle 308 can be different than the number in pulse cycle 306, the configuration of HSCV voltage ramps 313a-b may differ from voltage ramp 312a or 312b, and timing intervals 323-325 may vary from corresponding timing intervals 320-322.

During these HSCV pulse cycles the DLTS analysis can be idle and not processing data, and instead each individual HSCV voltage ramp (e.g., voltage ramp 312a) can be used to acquire, store, and process C-V data for that particular pulse cycle. In certain implementations, changes across different sets of C-V data corresponding to different HSCV voltage ramps provide snapshots of the evolving charge profile during a DLTS capacitance transient. For example, the evolving charge profile during the capacitance transient 310 can be observed using C-V data for voltage ramp 312a and C-V data for voltage ramp 312b. Furthermore, differences in the evolving charge profiles for different capacitance transients, such as between capacitance transient 310 and capacitance transient 311, can be observed. It should be appreciated that the evolving charge profile is determined for the particular conditions for a particular DLTS pulse cycle (e.g., temperature, etc.) and at the same time the overall DLTS measurement process is being performed.

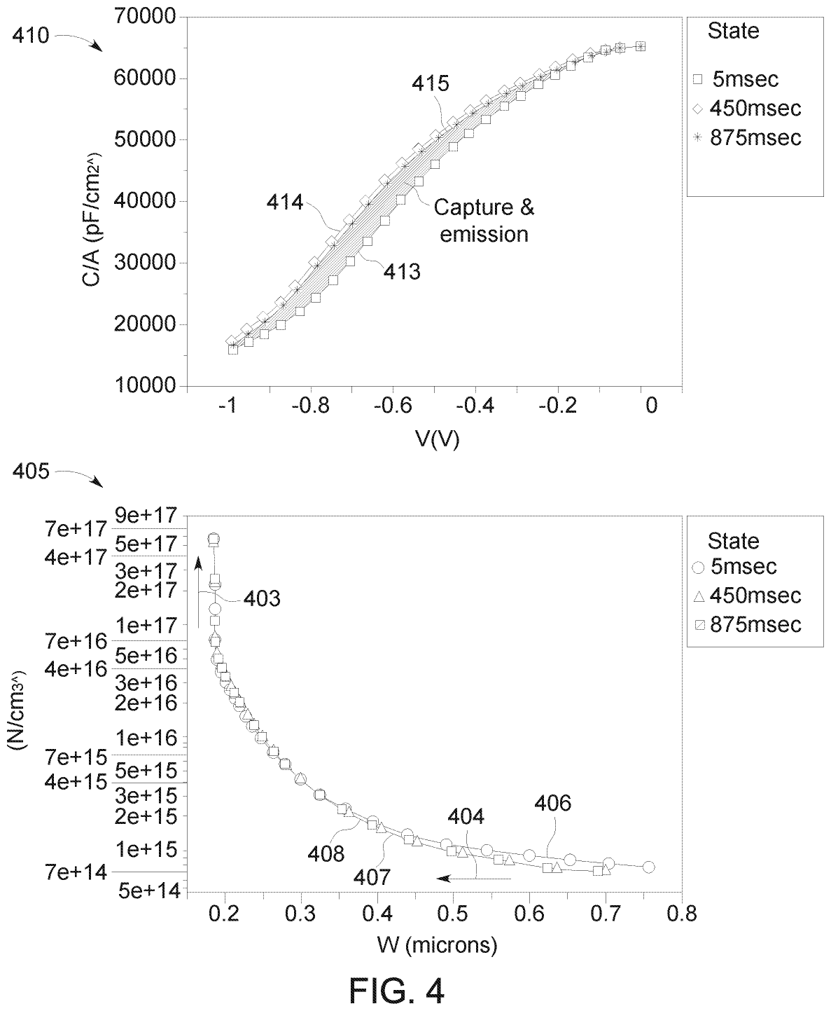

FIG. 4 depicts a series of traces representing an evolving charge profile during a capacitance transient. The traces correspond to three different time instances during the capacitance transient, as indicated by the 5 ms, 450 ms, and 875 ms legend entries. As an example, trace 413 for the capacitance versus voltage plots 410, which corresponds to performing a HSCV voltage ramp at 5 ms, represents 25 (the number of markers in trace 413) different pairs of capacitance (specifically, picofarads over centimeters squared) and voltage values over a voltage sweep range of about −1 to 0V. It should be appreciated that the particular orientation of the x-axis in plots 410, from −1 to 0V, may be for clarity purposes, and does not necessarily represent that the HSCV voltage ramp started at −1 and ended at 0V.

FIG. 4 illustrates that traces 414 and 415 are offset from trace 413, thereby indicating that the capacitance versus voltage relationship observed by a HSCV voltage ramp at 5 ms differs from the capacitance versus voltage relationship observed by a HSCV voltage ramp at 450 ms (and 875 ms). This change in the capacitance versus voltage relationship across the three traces represents the evolving charge profile during the capacitance transient at three different time instances.

The evolving charge profile can also be represented as in charge (in units of N, the number of units of electron charge e, per centimeter cubed) versus spatial depth (in units of microns) plots 405. The temporal sequence of traces 406, 407, and 408, corresponding to 5, 450, and 875 ms, respectively, illustrates that over time, during the capacitance transient, there is a transition to a greater charge density (e.g., arrow 403 in the direction of increasing charge density) in a shallower region of the DUT (e.g., arrow 404 in the direction of decreasing depth). Observing the evolving charge profile can provide information on the characteristics of the defects in the DUT. For example, some types of defects may trap and/or release charge carriers over a rapid timescale that cannot be determined using the disclosed techniques, therefore observation of an evolving charge profile can indicate the presence of particular types of defects.

It should be appreciated that the duration of interval 334 for the HSCV voltage ramp(s) are of a duration relative to the duration of the DLTS pulse phase (e.g., pulse 301) such that the HSCV measurements have a limited effect on the overall capacitance transient relative to pulse cycles without HSCV measurements. For example, the duration of the HSCV voltage ramp is selected to be shorter than a timing threshold based on the shorter of the times required to fill the charge-trapping defects during the pulse phase or the relaxation time constant during the relaxation phase. If the duration of the HSCV voltage ramp exceeds the timing threshold, the HSCV ramp may induce additional defect charging or relaxation.

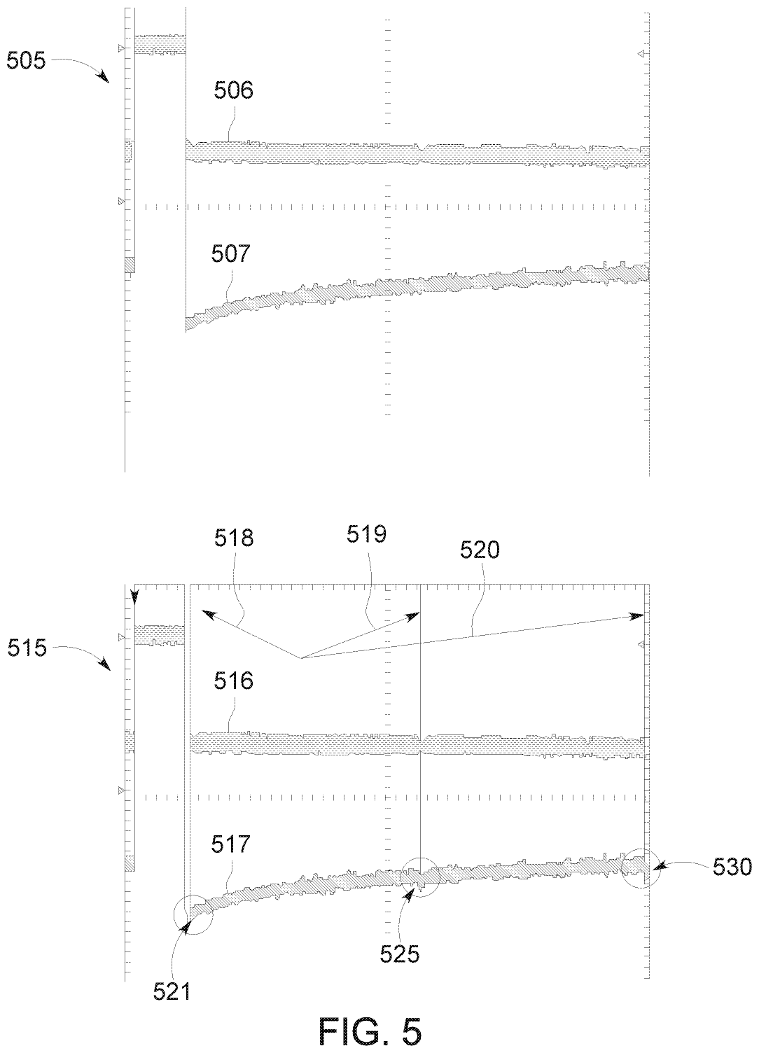

FIG. 5 illustrates an example of HSCV measurements creating perturbations on the overall capacitance transient. Plot 505 depicts a DLTS pulse sequence without any HSCV voltage ramps, with trace 506 representing the voltage signal having an initial pulse phase followed by a relaxation phase, and trace 507 representing the corresponding capacitance in a DUT. Plot 515 depicts a DLTS pulse sequence with three HSCV voltage ramps (e.g., voltage ramps 518, 519, 520), with trace 516 representing the voltage signal having an initial pulse phase followed by a relaxation phase that includes voltage ramps 518-520. Trace 517 represents the corresponding capacitance in a DUT, and capacitance deltas 521, 525, and 530 are perturbations in the capacitance transient relative to the capacitance transient shown in plot 505. It should be appreciated that the magnitude of the capacitance transient perturbations will increase as the timing duration of voltage ramps 518-520 increase, and vice versa.

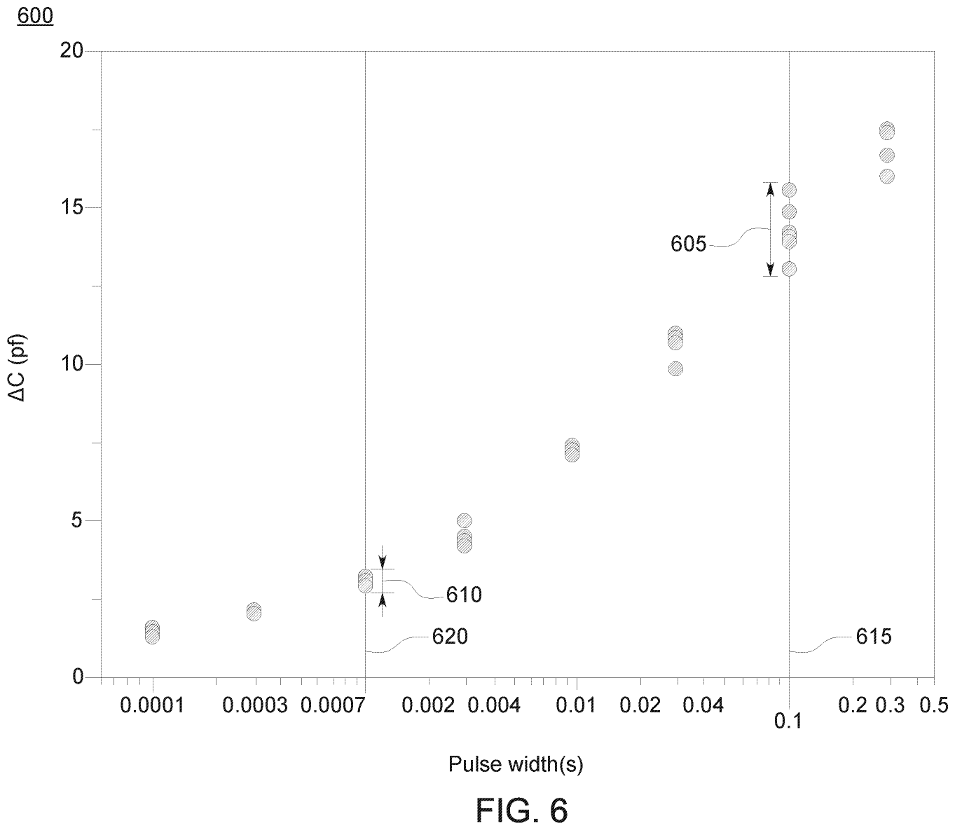

FIG. 6 illustrates an example plot 600 of the magnitude of capacitance transient perturbations for a DLTS pulse width of 100 ms (as depicted for FIG. 5) for different durations of a HSCV voltage ramp. For example, for a voltage ramp duration of 0.1 seconds (100 ms), as indicated by marker 615, observed capacitance deltas ranged from as little as about 12 pF to as much as about 15 pF, as indicated by capacitance perturbation range 605. As an example, for a DLTS pulse width of 100 ms, each voltage ramp duration of 100 ms during the relaxation phase of about 900 ms can create capacitance transient perturbations (e.g., capacitance deltas 521, 525, 530) of about 12 to about 15 pF.

Plot 600 indicates that as the HSCV voltage ramp timing duration increases, the magnitude of the capacitance transient perturbations increase, and vice versa. For example, when reducing the HSCV voltage ramp timing duration to 0.1 ms, as indicated by marker 620, the magnitude of the capacitance transient perturbations have a limited effect of about 2.5 pF of capacitance delta, capacitance perturbation range 610. In other words, for a DLTS pulse width of 100 ms, each voltage ramp duration of 1 ms during the relaxation phase of about 900 ms can create capacitance transient perturbations (e.g., capacitance deltas 521, 525, 530) of about 2.5 pF. It should be appreciated that plot 600 indicates that even small HSCV voltage ramp timing durations (e.g., 0.1 ms) induce a small step in capacitance (e.g., charge capture occurs). However, the overall capacitance transient characteristics are maintained, and the HSCV measurements can provide information on the change in charge profile from the beginning to the end of the capacitance transient.

Various implementations described herein may be implemented using any in a variety of standard or proprietary discrete electronics or integrated semiconductor processes. In addition, it should be noted that implementations are contemplated that may employ a much wider range of semiconductor materials and manufacturing processes including, for example, CMOS, CIGS, GaAs, SiGe, etc.

As indicated above, in some implementations, the apparatus and methods may be employed for characterization of photovoltaic materials and cells. For example, in addition to CIGS cells, aspects of the disclosure may be applied to cadmium-telluride (Cd—Te) cells, amorphous silicon (a-Si) cells, micro-crystalline silicon (Si) cells, crystalline silicon (c-Si) cells, and gallium arsenide (GaAs) multi-junction cells.

The multiplexed DLTS and HSCV measurement system as described herein may be represented (without limitation) in software (object code or machine code in non-transitory computer-readable media), in varying stages of compilation, as one or more netlists (e.g., a SPICE netlist), in a simulation language, in a hardware description language (e.g., Verilog, VHDL), by a set of semiconductor processing masks, and as partially or completely realized semiconductor devices (e.g., an ASIC). Some implementations may be a standalone integrated circuit, while others may be embedded as part of larger system, module, data acquisition platform, or test and measurement set up (e.g., SULA, SEMETROL).

It will be understood by those skilled in the art that changes in the form and details of the implementations described above may be made without departing from the scope of this disclosure. In addition, although various advantages have been described with reference to some implementations, the scope of this disclosure should not be limited by reference to such advantages. Rather, the scope of this disclosure should be determined with reference to the appended claims.

What is claimed is:

1. An apparatus comprising:
a first input configured to interface to a semiconductor device;
a first output configured to interface to the semiconductor device;
first circuitry configured to generate a set of waveform cycles at the first output, each cycle having:
a first temporal portion having a first signal configured to fill a set of charge-trapping defects in the semiconductor device with free carriers;
a second temporal portion having a second signal configured to cause a subset of the free carriers to retract from the set of charge-trapping defects based on a time constant;
a first subset of cycles corresponding to less than the entire set of waveform cycles further having:
a third signal and a fourth signal during the second temporal portion, the third signal and the fourth signal being configured to cause a corresponding number of free carriers filled and/or retracted from the set of charge-trapping defects to be within a constraint, the third signal occurring earlier than the second signal, the fourth signal occurring later than the second signal; and
second circuitry configured to measure a first set of capacitance characteristics at the first input based in part on the third signal and a second set of capacitance characteristics at the first input based in part on the fourth signal for determining a change in charge depth profiles in the semiconductor device at different times during the second temporal portion.

2. The apparatus of claim 1, wherein the semiconductor device is a photovoltaic cell.

3. The apparatus of claim 2, wherein the photovoltaic cell is a Copper-Indium-Gallium-Selenide (CIGS) photovoltaic cell.

4. The apparatus of claim 1, wherein a time duration for the third signal is selected such that a difference between a first sample value from a capacitance transient during the third signal and a second sample value from a second capacitance transient during the second temporal portion of a cycle not included in the first subset of cycles is below a threshold value.

5. The apparatus of claim 4, wherein the threshold value is about 3 pF.

6. The apparatus of claim 1, wherein the third signal has:
a time duration of about 1 ms;
about 25 voltage steps; and
a voltage range of about −1 V to about −0.2V.

7. The apparatus of claim 6, wherein the third signal and the fourth signal have the same time duration, number of voltage steps, and voltage range.

8. The apparatus of claim 1, wherein a single cycle in the first subset of cycles follows a single cycle not in the first subset of cycles.

9. The apparatus of claim 1, wherein each cycle in the first subset of cycles includes three voltage ramps for measuring capacitance characteristics at the first input for determining changes in charge depth profiles in the semiconductor device during the second temporal portion, the three voltage ramps including the third signal and the fourth signal.

10. The apparatus of claim 1, wherein a first subset of the set of charge-trapping defects corresponds to metastable defects that are responsive to at least one of light or hysteresis effects.

11. A method comprising:
generating a set of waveform cycles at a first output configured to interface to a semiconductor device, each cycle having:
a first temporal portion having a first signal configured to fill a set of charge-trapping defects in the semiconductor device with free carriers;
a second temporal portion having a second signal configured to cause a subset of the free carriers to retract from the set of charge-trapping defects based on a time constant;
a first subset of cycles corresponding to less than the entire set of waveform cycles further having:
a third signal and a fourth signal during the second temporal portion, the third signal and the fourth signal being configured to cause a corresponding number of free carriers filled and/or retracted from the set of charge-trapping defects to be within a constraint, the third signal occurring earlier than the second signal, the fourth signal occurring later than the second signal; and
measuring at a first input configured to interface to the semiconductor device a first set of capacitance characteristics based in part on the third signal and a second set of capacitance characteristics at the first input based in part on the fourth signal for determining a change in charge depth profiles in the semiconductor device at different times during the second temporal portion.

12. The method of claim 11, wherein the semiconductor device is a photovoltaic cell.

13. The method of claim 12, wherein the photovoltaic cell is a Copper-Indium-Gallium-Selenide (CIGS) photovoltaic cell.

14. The method of claim 11, wherein a time duration for the third signal is selected such that a difference between a first sample value from a capacitance transient during the third signal and a second sample value from a second capacitance transient during the second temporal portion of a cycle not included in the first subset of cycles is below a threshold value.

15. The method of claim 14, wherein the threshold value is about 3 pF.

16. The method of claim 11, wherein the third signal has:
a time duration of about 1 ms;
about 25 voltage steps; and
a voltage range of about −1 V to about −0.2V.

17. The method of claim 16, wherein the third signal and the fourth signal have the same time duration, number of voltage steps, and voltage range.

18. The method of claim 11, wherein a single cycle in the first subset of cycles follows a single cycle not in the first subset of cycles.

19. The method of claim 11, wherein each cycle in the first subset of cycles includes three voltage ramps for measuring capacitance characteristics at the first input for determining changes in charge depth profiles in the semiconductor device during the second temporal portion, the three voltage ramps including the third signal and the fourth signal.

20. The method of claim 11, wherein a first subset of the set of charge-trapping defects corresponds to metastable defects that are responsive to at least one of light or hysteresis effects.

21. A computer program product comprising computer-readable program code to be executed by one or more processors when retrieved from a non-transitory computer-readable medium, the program code including instructions configured to cause:
generating a set of waveform cycles at a first output configured to interface to a semiconductor device, each cycle having:
a first temporal portion having a first signal configured to fill a set of charge-trapping defects in the semiconductor device with free carriers;
a second temporal portion having a second signal configured to cause a subset of the free carriers to retract from the set of charge-trapping defects based on a time constant;
a first subset of cycles corresponding to less than the entire set of waveform cycles further having:
a third signal and a fourth signal during the second temporal portion, the third signal and the fourth signal being configured to cause a corresponding number of free carriers filled and/or retracted from the set of charge-trapping defects to be within a constraint, the third signal occurring earlier than the second signal, the fourth signal occurring later than the second signal; and
measuring at a first input configured to interface to the semiconductor device a first set of capacitance characteristics based in part on the third signal and a second set of capacitance characteristics at the first input based in part on the fourth signal for determining a change in charge depth profiles in the semiconductor device at different times during the second temporal portion.
